(19) United States
(12) Patent Application Publication
(10) Pub. No.: US 2014/0209988 A1
(43) Pub. Date: Jul. 31, 2014

(54) NONVOLATILE MEMORY BITCELL

(71) Applicants: Xin Lin, Phoenix, AZ (US); Hongning Yang, Chandler, AZ (US); Zhihong Zhang, Chandler, AZ (US); Jiang-Kai Zuo, Chandler, AZ (US)

(72) Inventors: Xin Lin, Phoenix, AZ (US); Hongning Yang, Chandler, AZ (US); Zhihong Zhang, Chandler, AZ (US); Jiang-Kai Zuo, Chandler, AZ (US)

(73) Assignee: FREESCALE SEMICONDUCTOR, INC., Austin, TX (US)

(21) Appl. No.: 13/756,248

(22) Filed: Jan. 31, 2013

(51) Int. Cl. H01L 29/66; H01L 27/088

(52) U.S. Cl. CPC H01L 29/66825; H01L 27/088
USPC 257/298; 438/258

(57) ABSTRACT

A multiple time programmable nonvolatile memory device having a single polysilicon memory cell includes a select transistor and a bitcell transistor. The bitcell transistor has asymmetrically configured source, drain, and channel regions including asymmetrically configured source-body and drain-body junctions. Compared with the drain-body junction, the impurity concentration gradient of the source-body junction is more gradual, which may significantly improve program disturb immunity. The bitcell transistor gate may be connected to an electrode of a coupling capacitor, but may be otherwise floating or Ohmically isolated. The floating gate of the bitcell is protected by a dielectric layer for potentially improved data retention.

### BACKGROUND

1. Field

Disclosed subject matter is in the field of semiconductor memory devices and, more specifically, non-volatile memory devices.

2. Related Art

Non-volatile memory (NVM) devices include multi-programmable NVM devices that employ channel hot electrons to program a bitcell and Fowler-Nordheim tunneling to erase the bitcell. Some NVM devices include an electrically isolated or floating polycrystalline silicon (polysilicon) gate and some of these designs require two different layers of polysilicon, a first polysilicon layer for the floating gates and a second polysilicon layer for the accessible or control gates. While floating gate technology is well developed, a process that requires two polysilicon layers imposes significant compatibility and cost issues. In contrast, in many embedded applications, when the number of memory devices required is relatively small, the processes that employ a single polysilicon layer to fabricate the NVM devices are more cost-effective and more compatible with standard CMOS logic process technologies. To reduce or avoid additional process cost, the embedded NVM devices are often fabricated using the existing process steps that are used and typically optimized for other devices on the same chip, such as for the logic transistors or power devices. However, such NVM devices tend to exhibit performance or reliability issues such as program disturb vulnerability, especially for large arrays.

### BRIEF DESCRIPTION OF THE DRAWINGS

The present invention is illustrated by way of example and is not limited by the accompanying figures, in which like references indicate similar elements. Elements in the figures are illustrated with an emphasis on clarity and simplicity where possible and have not necessarily been drawn to scale.

FIG. 1 is a circuit diagram of selected portions of a nonvolatile memory cell array;

FIG. 2 depicts an individual memory cell of the cell array depicted in FIG. 1;

FIG. 3 is a cross-sectional view of a substrate at a selected stage in the fabrication of a nonvolatile memory device;

FIG. 4 depicts a layout of selected elements of the memory cell of FIG. 3;

FIG. 5 is a cross-section of a substrate at a first stage in a process for fabricating a nonvolatile memory;

FIG. 6 depicts a stage in the fabrication process subsequent to FIG. 5, illustrating the formation of select transistor and bitcell transistor gates;

FIG. 7 depicts processing subsequent to FIG. 6 illustrating the formation of lightly-doped source and drain regions and a halo distribution in the substrate including asymmetrically configured source-drain regions for the bitcell transistor;

FIG. 8 depicts processing subsequent to FIG. 7 in which a dielectric layer is formed overlying the bitcell transistor gate and the source and drain regions of the bitcell transistor;

FIG. 9 depicts processing subsequent to FIG. 8 in which heavily-doped source-drain regions are formed in the substrate;

FIG. 10 depicts processing subsequent to FIG. 9 in which a heavily-doped region of a different conductivity type is introduced into the substrate to form an ohmic contact with a well region; and

FIG. 11 illustrates program disturb immunity for a memory cell fabricated in a conventional manner versus a memory cell fabricated as described with respect to FIG. 5 through FIG. 10.

### DETAILED DESCRIPTION

Embodiments of disclosed NVM arrays may include a memory cell, also referred to herein as a bitcell, that includes a first transistor, referred to herein as a select transistor, and a second transistor referred to herein as a bitcell transistor. In some embodiments, the gate of the select transistor is connected to a selectable word-line, the source is grounded, and the drain is connected, through the source-drain terminals of the bitcell transistor to a bit-line. The gate of the bitcell transistor may be an electrically isolated or “floating” gate, i.e., there is no conductive current path to or from the bitcell transistor gate. If sufficient charge is programmed onto the floating gate, the bitcell transistor's current path will be shut off or substantially shut off. Even with the select gate turned on, a negligible low current will flow through the bitcell. If, on the other hand, the bitcell transistor gate is erased, the resistivity of the bitcell transistor's current path will drop, which results in a large current flowing through the bitcell when the bitcell is selected.

For a memory cell with a bit cell transistor having a channel length of approximately 0.1 to 1.0 micrometers, and a width/length ratio (W/L) between 0.5 and 5.0, programming a bitcell may include grounding (i.e., applying 0 V to) the source terminal of the select transistor, driving the bit-line voltage to 2 V to 6 V, applying approximately 2 V to 6 V to the select transistor gate, and applying approximately 2 V to 6 V to a control gate for a duration of approximately 0.1 to 2.0 milliseconds (ms). Erasing such a bitcell may include biasing the memory cell as follows: grounding the select transistor source and the bit-line, applying approximately 2 V to 6 V to the select transistor gate and approximately −6 V to −20 V to the control gate for a duration of approximately 0.1 to 2.0 seconds.

One of the challenges that the single polysilicon NVM technologies have faced is that the bitcell may be vulnerable to program disturb, which limits the achievable array size. Program disturb refers to the unintended programming or operation of a memory cell that is not selected. Program disturb can exhibit as a drain disturbance to bitcells on an unselected row or word-line, of a selected column or bit-line. For these unselected memory cells, the word-line is OFF, but the bit-line and control gate are HIGH. Program disturb can also encompass gate disturbance to bitcells on a selected row of an unselected column (i.e., word-line ON, bit-line GROUND, control gate HIGH).

Disclosed single polysilicon NVM embodiments include an asymmetric bitcell transistor in which an impurity concentration gradient, also sometimes referred to as a dopant concentration gradient, at the transistor's source-body junction differs from the impurity concentration gradient at the transistor's drain-body junction. For purposes of this disclosure, an impurity concentration gradient refers to a net change in impurity concentration over a finite distance. In the context of the impurity concentration gradient across a p-n junction, the p-type concentration on one side of the junction may be indicated as a positive value and the n-type impurity concentration may be indicated as a negative value for purposes of determining a numerical value of the impurity concentration gradient. Moreover, to the extent that an ideal junction transitions from one impurity concentration to a different impurity concentration over a distance of zero (0), a predetermined finite distance may be employed for purposes of determining a numerical value. In such cases, the impurity concentration gradients of two different p-n junctions may be compared qualitatively by comparing the impurity concentration differences across the two junctions. In the disclosed embodiments, an impurity concentration gradient of the bitcell transistor source-body junction is less than an impurity concentration gradient of the bitcell transistor drain-body junction. Asymmetric source-body and drain-body junctions in the bitcell transistor may improve bitcell operation and disturb immunity.

In some embodiments, a bitcell transistor drain region includes a proximal drain region, which is proximal to the transistor's channel region, and a distal drain region, which is displaced from the channel region. In these embodiments, the bitcell transistor proximal drain region may be formed with a low energy or shallow implant, referred to herein as the n-extension or NEXT implant. The NEXT implant may be implemented as a chain implant, including a top n-type implant and a bottom p-type implant. In at least one embodiment, the n-type implant is performed at a 0° tilt angle while the p-type implant is performed with a relatively large tilt angle, e.g., a tilt angle greater than 15°. The drain-body junction formed by the NEXT implant may be relatively abrupt and an impurity concentration gradient at the drain-body junction may be relatively large, which increases hot carrier injection efficiency during programming. In contrast, the bitcell transistor source region may be formed with a higher voltage or deeper, n-type implant, referred to herein as an NLDD implant, either with or without the NEXT implant. Compared with an impurity concentration gradient at the drain-body junction, the impurity concentration gradient at the source-body junction may be relatively lower, which suppresses band-to-band tunneling on the source side of unselected bitcells of a selected bit-line during programming, consequently minimizing the drain disturb. Moreover, the lower channel doping on the source side may slightly lower the bitcell transistor's natural threshold voltage, which enhances the gate disturb immunity. The source-body junction may be made still less abrupt by performing a shallow or low voltage p-type implant, referred to herein as a PLDD implant.

During fabrication, the bitcell transistor floating gate may be protected with a dielectric layer to prevent formation of silicide on the top of the floating gate. In at least one embodiment, this silicide prevention layer is formed before the high-dose source-drain implant, which may prevent the source-drain implant from reaching the bitcell transistor gate, which might further improve data retention. However, in another embodiment, the dielectric layer could be formed after the source-drain implant. The dielectric layer could be formed with silicon dioxide, silicon nitride, or a combination of layers of these materials.

In one aspect, the disclosed subject matter describes a method of fabricating a multiple-time programmable NVM device having a memory cell that includes a single layer of polycrystalline silicon or another suitable gate material and includes a bitcell transistor with asymmetrically configured source-body and drain-body junctions including a relatively abrupt drain-body junction and a relatively gradual source-body junction. The disclosed memory cell may beneficially exhibit robust program disturb immunity.

The method includes forming a select transistor gate overlying a select transistor channel region of a substrate and forming a bitcell transistor gate overlying a bitcell transistor channel region of the substrate. The nonvolatile memory may include a single layer of polysilicon or another gate material, and the select transistor and bitcell transistor gates may be formed contemporaneously by a common set of process steps.

Some embodiments of the bitcell transistor have asymmetric source and drain regions that include a relatively shallow and relatively heavily-doped region, referred to herein as the proximal drain region, formed adjacent or proximal to the bitcell transistor channel region, and a relatively deep and relatively lightly-doped source region, formed adjacent to an opposite end of the bitcell transistor channel region. In some of these asymmetric embodiments, the drain-body junction of the bitcell transistor is more abrupt than the source-body junction, i.e., an impurity concentration gradient in the vicinity of the drain-body junction is greater than an impurity concentration gradient in the vicinity of the source-body junction.

The substrate may be silicon or another type of semiconductor and may include a buried layer and an oppositely doped well region overlying the buried layer. The buried layer and the source and drain regions of the bitcell transistor may all have a first conductivity type, e.g., n-type, and the well region may have a second and opposite conductivity type, e.g., p-type.

Embodiments of the method may include performing a halo implant of a dopant with the second conductivity type to form a halo distribution and performing an extension implant of a dopant with the first conductivity type to form the proximal drain region of the bitcell transistor. In some embodiments, the halo distribution is deeper and less heavily doped than the proximal drain region. The halo implant may be performed with a relatively large tilt angle, while the extension implant may be performed without a significant tilt angle. In various embodiments, the halo implant and the extension implant may share the same implant photo-resist mask. In other embodiments, these two implants can be implemented using different photo-resist masks.

In at least one embodiment, the method includes forming a relatively deep and relatively lightly-doped bitcell transistor source region using an LDD implant of a dopant with the first conductivity type. The halo implant and the extension implant may be masked with respect to the bitcell transistor source region. To reduce the abruptness of the bitcell transistor source-body junction, a relatively low energy or shallow implant of a dopant with the second conductivity type may be performed in the bitcell transistor source region.

In some embodiments, a heavily-doped select transistor source region and a heavily-doped select transistor drain region may be formed adjacent to either side of a select transistor channel region. In some embodiments, spacers may be formed on sidewalls of the select transistor gate before forming the heavily-doped source and heavily-doped drain regions.

Prior to forming the heavily-doped select transistor source region and the heavily-doped select transistor drain region, a dielectric layer may be formed overlying the bitcell transistor gate, the bitcell transistor source region, and the bitcell transistor drain region. In these embodiments, the dielectric layer may block the implant that forms the select transistor source and drain regions. In addition, the dielectric layer may also serve to prevent the formation of silicide in the bitcell transistor.

In some embodiments, the method may further include forming a coupling capacitor including a first plate, a capacitor dielectric underlying the first plate, and a substrate plate. The first plate may be a polysilicon plate connected to the bitcell transistor gate. Like the bitcell transistor gate, the first plate of the coupling capacitor and the polysilicon connecting the bitcell transistor gate and the first plate of the coupling capacitor are covered by the dielectric layer. The substrate plate may include a central portion underlying the first capacitor plate and a substrate tie surrounding the central portion. In this embodiment, the substrate tie includes a first portion having the first conductivity type and a second portion having the second conductivity type. In another embodiment, the entire substrate tie may be doped with the same conductivity type as the substrate plate.

In another aspect, at least one embodiment of a nonvolatile memory device includes an array of memory cells. Each of the memory cells may include a select transistor and a bitcell transistor. The select transistor includes a select transistor gate overlying a select transistor gate dielectric and a select transistor channel region. The select transistor may further include a select transistor source region and a select transistor drain region on either side of the select transistor channel region.

At least one embodiment of the bitcell transistor includes a bitcell transistor gate overlying a bitcell transistor gate dielectric and a bitcell transistor channel region. The bitcell transistor may further include a bitcell transistor source region positioned between the select transistor drain region and the bitcell transistor channel region. In this embodiment, the select transistor drain region is adjacent to the bitcell transistor source region. In other embodiments, the select transistor drain region may be electrically coupled to the bitcell transistor source region by an interconnect or one or more metal lines.

In some embodiments, a drain of the bitcell transistor includes a first region, referred to herein as the proximal drain region, adjacent to the bitcell transistor channel region, and a second region, referred to herein as the distal drain region that is displaced with respect to the bitcell transistor channel region. In these embodiments, the proximal drain region is positioned between the bitcell transistor channel region and the distal drain region. In asymmetric embodiments of the bitcell transistor, the bitcell transistor source region may be relatively deep and relatively lightly-doped while the bitcell transistor proximal drain region may be relatively shallow and heavily-doped. The bitcell transistor gate may be an electrically-isolated transistor gate.

In another aspect, an embodiment of a disclosed method of fabricating a nonvolatile memory includes forming a memory cell or a plurality of memory cells in a cell array. The memory cell may include a select transistor with symmetrically configured source and drain regions, and a bitcell transistor with asymmetrically configured source-body and drain-body junctions and an Ohmically isolated transistor gate. A drain region of the select transistor is electrically connected to a source of the bitcell transistor. The select transistor may include heavily-doped source and drain regions. The bitcell transistor may include a relatively lightly-doped source, a relatively heavily-doped drain region, and a non-uniform channel with a higher dopant concentration near the drain region. A gate of the select transistor and a gate of the bitcell transistor may both be formed during a single gate formation sequence.

The method may further include forming a coupling capacitor that includes a first plate, a capacitor dielectric underlying the first plate, and a substrate plate. The first plate may be a polysilicon plate and the substrate plate may include a central portion underlying the first capacitor plate and a substrate tie surrounding the central portion. The substrate tie may include a first portion having the first conductivity type and a second portion having the second conductivity type. In another embodiment, the entire substrate tie may be doped with the same conductivity type as the substrate plate.

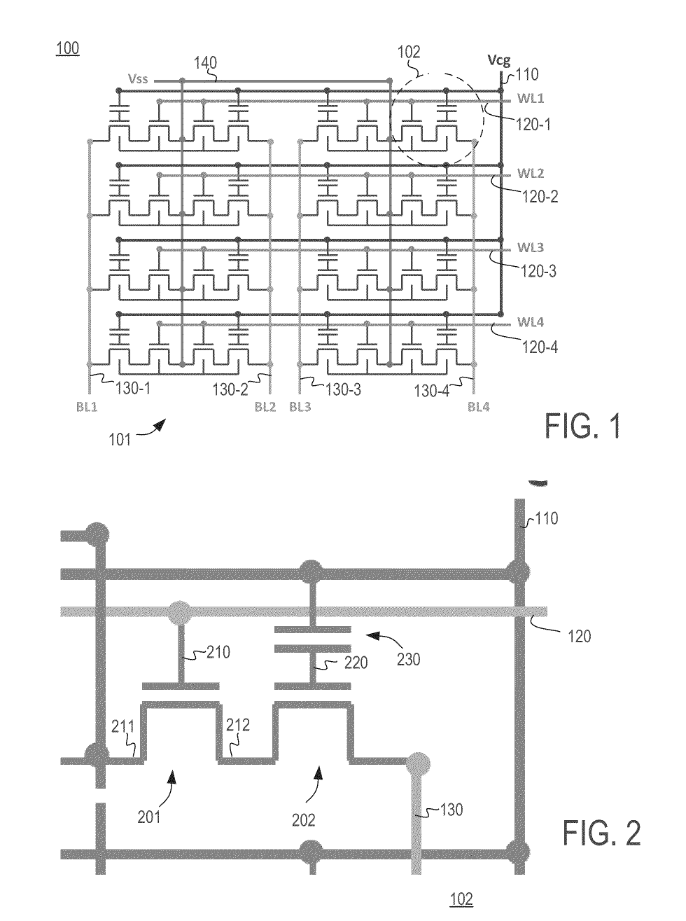

Turning now to the drawings, FIG. 1 depicts selected elements of an embodiment of a nonvolatile memory device 100. In the depicted embodiment, nonvolatile memory device 100 includes an array 101 of memory cells 102. Each memory cell 102 is a bitcell exhibiting one of two logical states. Referring to FIG. 2 in parallel with FIG. 1, programmable memory cell 102 includes a select transistor 201 in combination with a bitcell transistor 202 which features a floating gate 220. During a programming cycle, electrons are stored on floating gate 220. The presence of static charge at floating gate 220 may alter the threshold voltage of the bitcell transistor 202. If bitcell transistor 202 is sufficiently programmed, select transistor 201 conducts negligible current between drain region 212 and source 211 when select transistor gate 210 is maintained at a logically high voltage, which occurs when the corresponding word-line 120 is high. In this manner, the current flowing through bit-line 130 will indicate whether floating gate 220 has been programmed or not.

As depicted in FIG. 1, the portion of array 101 shown includes a total of sixteen memory cells 102. Each memory cell 102 is associated with one of the four word-lines 120-1 through 120-4 and is associated with one of the four bit-lines 130-1 through 130-4. The potential of control gate 110 is coupled to floating gate 220 through coupling capacitor 230. Control gate 110 is biased with a positive potential when programming memory cell 102 of memory array 101. When erasing memory cell 102 of memory array 101, a negative voltage is applied on control gate 110. When not programming or erasing, control gate 110 is biased with the positive voltage equivalent to that during programming to simplify the peripheral circuits. FIG. 1 further depicts a ground terminal 140 shown as connected to VSS or ground. The bias conditions for operating memory cell 102 of memory array 101 are only exemplary and other bias conditions may be applied to program, erase, and read memory cell 102.

Memory cells in array 101 may be inadvertently and unintentionally programmed or erased when electrical fields caused by programming cycles impact the amount of charge stored on a floating gate 220 of an unselected memory cell. For example, if nonvolatile memory device 100 is programming the memory cell 102 associated with word-line 1 (120-1) and bit-line 4 (130-4), maintaining bit-line 4 (130-4) and word-line 1 (120-1) at voltages designated for a programming cycle may inadvertently program a memory cell 102 that shares the same bit-line 130-4 and/or shares the same word-line 120-1.

In some embodiments, the memory cells 102 of nonvolatile memory device 100 are n-channel devices. In other embodiments, array 101 may be implemented with p-channel devices. With respect to memory cell 102 as depicted in FIG. 1 and FIG. 2, programming the bitcell may include programming by channel hot electrons under conditions in which the VSS terminal 140 is maintained at 0 V, the bit-line 130 is maintained at a relatively high voltage in the range of approximately 2.0 to 6.0 V, the word-line 120 is maintained at a voltage in the range of approximately 2.0 to 6.0 V, and control gate 110 is maintained at a voltage in a range of approximately 2.0 to 6.0 V for a duration on the order of about 0.1 to 2.0 ms.

In some implementations of array 101 as depicted in FIG. 1, erasing of memory cell 102 occurs by Fowler Nordheim tunneling under conditions in which VSS terminal 140 is 0 V, the bit-line voltage is 0 V, the word-line voltage is in the range of approximately 2.0 to 6.0 V, and control gate 110 is maintained at a voltage of approximately −6 to −20 V for a duration of approximately 0.1 to 2.0 seconds.

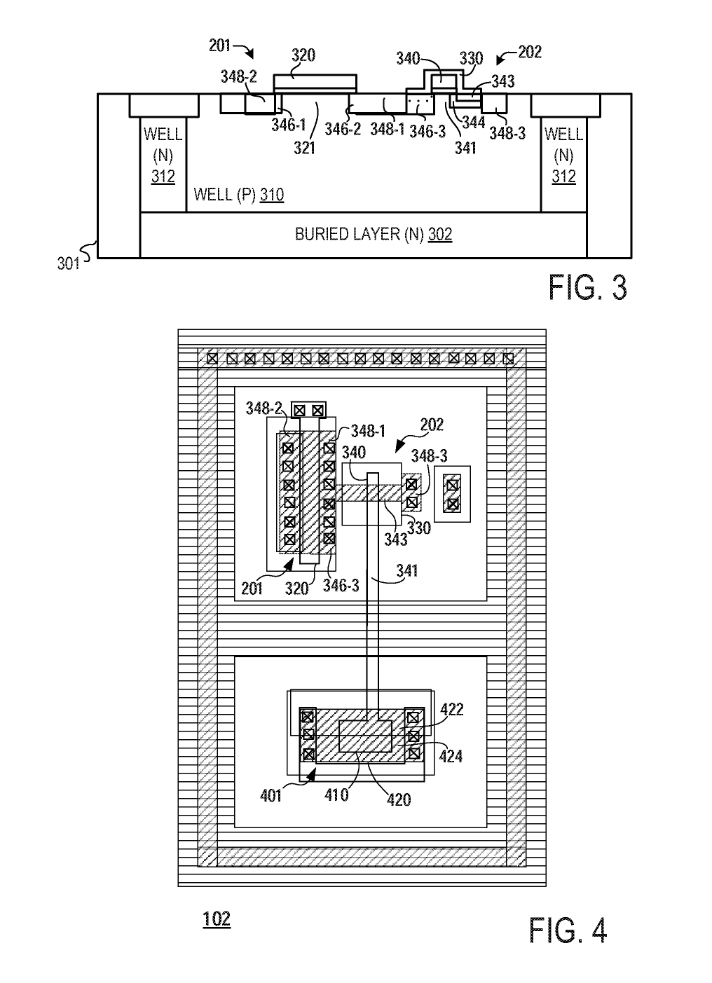

Referring now to FIG. 3 and FIG. 4, a cross-sectional view (FIG. 3) and a layout view (FIG. 4) of selected elements of a memory cell 102 as depicted in FIG. 1 and FIG. 2 are shown.

FIG. 3 depicts memory cell 102 in cross-section. As depicted in FIG. 3, memory cell 102 includes substrate 301, which may be part of a semiconductor wafer or some other form of bulk substrate (not depicted). As depicted in FIG. 3, substrate 301 may be a single crystal semiconductor such as crystalline silicon or any other suitable semiconductor material. FIG. 3 depicts selected elements or regions of substrate 301 located near an upper surface of substrate 301, some of which are relatively lightly-doped and some of which are relatively heavily-doped, some of which are p-type, and some of which are n-type. As shown in FIG. 3, substrate 301 includes a buried layer 302 of a first conductivity type (e.g., n). Overlying buried layer 302 is a well region 310 of a second conductivity type (e.g., p) located between a pair of well regions 312. Well regions 310 and 312 may be either n-type or p-type. For the sake of clarity, the depicted implementation will be described with respect to an implementation in which well region 310 is a p-type region and select transistor 201 and bitcell transistor 202 are n-channel devices. In this implementation, second well region 312 and buried layer 302 are n-type regions.

In some embodiments, memory cell 102 is built on silicon-on-insulator (SOI) technology. In these embodiments, buried layer 302 and well regions 312, which are used for device isolation primarily, become optional, since the memory cells could be isolated from each other by dielectric layers including a buried oxide (BOX) layer.

Memory cell 102 includes a select transistor 201 and a bitcell transistor 202. In the FIG. 3 embodiment, select transistor 201 includes a select transistor gate 320 overlying a select transistor channel region 321 in well region 310. A heavily dope n-type select transistor drain region 348-1 and a heavily doped n-type select transistor source region 348-2 are laterally aligned to select transistor gate 320 and are positioned within well region 310 adjacent to either end of select transistor channel region 321. Select transistor 201 as depicted in FIG. 3 further includes relatively lightly doped n-type regions referred to in herein as lightly-doped drain (LDD) regions 346-1 and 346-2. LDD regions 346 serve to reduce hot carrier injection during operation of select transistor 201 and improve the breakdown voltage of select transistor 201.

The embodiment of bitcell transistor 202 depicted in FIG. 3 includes a bitcell transistor gate 340 overlying a bitcell transistor channel region 341 within well region 310. The FIG. 3 embodiment of bitcell transistor 202 includes a bitcell transistor source region 346-3 aligned to bitcell transistor gate 340 and located within well region 310 adjacent to bitcell transistor channel region 341. The drain of bitcell transistor 202 as depicted in FIG. 3 includes a bitcell transistor proximal drain region 343 aligned to bitcell transistor gate 340 and located within well region 310 adjacent to transistor channel region 341. Proximal drain region 343 as shown in FIG. 3 is positioned between bitcell transistor channel region 341 and a heavily doped n-type region, referred to herein as bitcell transistor distal train region 348-3. In the embodiment depicted in FIG. 3, well region 310 functions as a bitcell transistor body for bitcell transistor 202 and as a select transistor body for select transistor 201. Bitcell transistor source region 346-3 region forms a junction, referred to herein as the source-body junction at the interface between bitcell transistor source region 346-3 and well region 310. Similarly, bitcell transistor proximal drain region 343 forms a drain-body junction at an interface between proximal drain region 343 and well region 310.

The FIG. 3 embodiment of bitcell transistor 202 includes an asymmetric source-drain configuration in which the doping impurity and distribution within the bitcell transistor source region 346-3 differs from the doping and impurity distribution of bitcell transistor proximal drain region 343. In some embodiments, for example, differences in doping concentration between bitcell transistor source region 346-3 and bitcell proximal bitcell transistor proximal drain region 343 produce impurity concentration gradient differences between a source-body junction and a drain-body junction, where the well region 310 depicted in FIG. 3 functions as a transistor body of select transistor 201 and bitcell transistor 202 and the source-body junction of bitcell transistor 202 occurs at the interface between bitcell transistor source region 346-3 and well region 310 while the drain-body junction of bitcell transistor 202 occurs at an interface between bitcell transistor proximal drain region 343 and well region 310.

In the FIG. 3 embodiment, bitcell transistor 202 further includes a p-type halo distribution 344 that is deeper than proximal drain region 343 so that halo distribution 344 encompasses proximal drain region 343. Bitcell transistor 202 also includes a relatively heavily-doped region referred to herein as bitcell transistor distal drain region 348-3. In the depicted embodiment, bitcell transistor distal drain region 348-3 is positioned adjacent to bitcell transistor proximal drain region 343 with proximal drain region 343 being positioned between distal drain region 348-3 and bitcell transistor channel region 341. In this embodiment, distal drain region 348-3 is laterally displaced from bitcell transistor channel region 341 by a distance equal to a width of proximal drain region 343. On the source side of transistor 202, the depicted implementation includes a relatively deep but relatively lightly-doped bitcell transistor source region 346-3, which may be formed during the same process that produces lightly-doped select transistor source region 346-1 and lightly-doped drain region 346-2 within select transistor 201. In this embodiment, the impurity concentration gradient at the source-body junction of bitcell transistor 202, i.e., the junction between bitcell transistor source region 346-3 and well region 310, is lower than the impurity concentration gradient at the drain-body junction, i.e., the junction between bitcell transistor proximal drain region 343 and well region 310.

FIG. 3 further depicts a dielectric layer 330 formed overlying bitcell transistor gate 340. In some embodiments, dielectric layer 330 functions to block the implant that forms the heavily-doped regions 348-1 and 348-2 and thereby prevent the formation of an abrupt source-body junction.

In the embodiment depicted in FIG. 3, select transistor drain region 348-1 and bitcell transistor source region 346-3 comprise an electrically contiguous region of substrate 301. However, in other embodiments, select transistor drain region 348-1 and bitcell transistor source region 346-3 may be physically and electrically distinct regions of substrate 301 that are electrically tied together with an interconnection of metal or another conductive material.

Referring now to FIG. 4, a top view of selected elements of an embodiment of memory cell 102 is shown. FIG. 4 depicts select transistor gate 320 of select transistor 201 defining the select transistor drain region 348-1 and the select transistor source region 348-2. FIG. 4 further depicts the bitcell transistor 202 including the bitcell transistor gate 340 which defines the bitcell transistor proximal drain region 343 and bitcell transistor source region 346-3.

FIG. 4 also illustrates bitcell transistor gate 340 connected to a coupling capacitor 401 (e.g., coupling capacitor 230, FIG. 2). In some embodiments, bitcell transistor gate 340 is a floating gate or Ohmically isolated gate. As depicted in FIG. 4, bitcell transistor gate 340 is connected only to a first electrode of coupling capacitor 401. Coupling capacitor 401 as depicted in FIG. 4 includes a top plate 410 comprised of a portion of the same polysilicon structure that forms bitcell transistor gate 340, and a capacitor dielectric that includes the gate dielectric formed underlying the top plate 410 (not visible as shown in FIG. 4). Coupling capacitor 401 further includes a bottom plate referred to herein as substrate plate 420. Substrate plate 420 comprises a substrate tie surrounding the polysilicon top plate 410. In the embodiment depicted in FIG. 4, the substrate plate 420 includes a first portion 422 and a second portion 424, which are of opposite conductivity types. If, for example, first portion 422 has p-type conductivity, second portion 424 has n-type conductivity. In other embodiments, the entire substrate plate 420 may be doped with dopant species of one conductivity type.

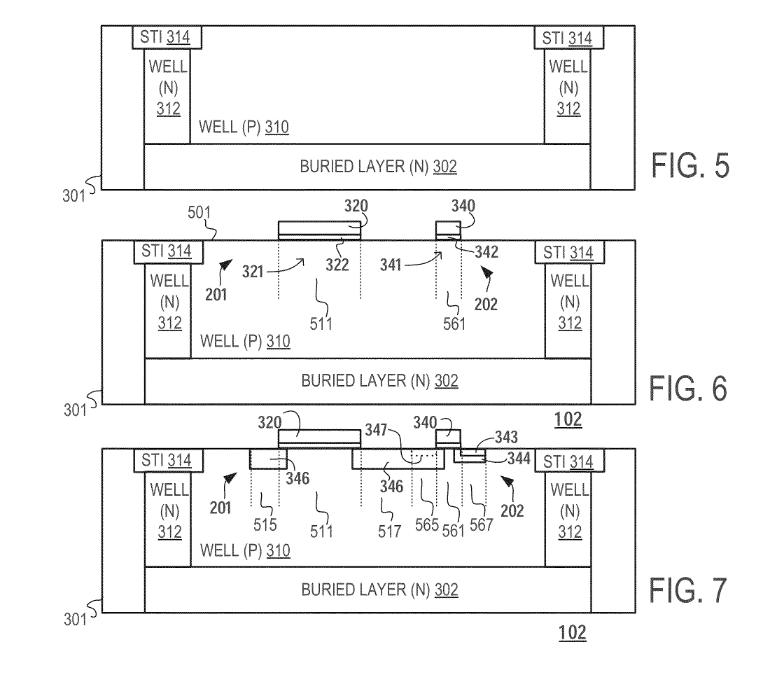

Turning now to FIG. 5 through FIG. 10, a series of cross-sections showing selected steps in the fabrication of nonvolatile memory device 100 are depicted. The cross-sections are not intended to depict every processing step required to produce the device and the cross sections depict only one embodiment of fabricating the device. Numerous variations of the described steps including variations in the sequence of performing the steps may be possible.

FIG. 5 depicts substrate 301 that includes a buried layer 302 and a well region 310 overlying buried layer 302. Substrate 301 may represent a portion of a semiconductor wafer. In some embodiments, substrate 301 is a substantially monocrystalline semiconductor such as silicon or another suitable semiconductor and includes a bulk portion (not depicted) underlying buried layer 302. Depending upon the implementation, substrate 301 may include a buried insulating layer, one or more epitaxial layers, one or more extrinsically-doped semiconductor regions, and so forth.

The labeling of elements indicated in FIG. 5 includes the letter n or the letter p in parentheses to indicate a possible extrinsic doping type or conductivity type of the corresponding region. It will be understood, however, that a region indicated in parentheses as an n-type region may be implemented with a p-type region in a different embodiment. The extrinsic doping types indicated may, however, indicate the relative conductivity types of two regions. If, for example, well region 310 is indicated as p-type and buried layer 302 is indicated as n-type, it will be understood that if well region 310 were implemented with n-type doping, buried layer 302 would be implemented with p-type doping.

FIG. 5 further depicts isolation regions, referred to as shallow trench isolation regions 314 and second well regions 312. Second well region 312 is indicated in FIG. 5 with a conductivity type that is the same as buried layer 302 and different from the conductivity type indicated for well region 310. In this manner, well region 310 can be electrically isolated from other regions of substrate 301. Shallow trench isolation structures 314 may include an insulating material such as a thermally formed and/or a deposited silicon dioxide.

Turning now to FIG. 6, a select transistor gate 320, and a bitcell transistor gate 340 are formed overlying an upper surface 501 of substrate 301. In the FIG. 6 embodiment, select transistor gate 320 is an electrically conductive or semi-conductive material overlying a select transistor gate dielectric 322 and a select transistor channel region 321 in well region 310. Similarly, bitcell transistor gate 340 may be an electrically conductive or semi-conductive material overlying a bitcell transistor gate dielectric 342 and a bitcell transistor channel region 341 in well region 310. Select transistor gate 320 is vertically aligned with a select transistor channel zone 511 of well region 310 of substrate 301. Similarly, bitcell transistor gate 340 is aligned overlying a bitcell transistor channel region zone 561 in well region 310 of substrate 301.

In some embodiments, select transistor gate 320 and the bitcell transistor gate 340 are formed substantially at the same time or contemporaneously. In these embodiments, a single deposition step may be used to form the conductive or semiconductive material that is subsequently patterned to achieve the transistor gates depicted in FIG. 6. In some embodiments, the material used for select transistor gate 320 and bitcell transistor gate 340 is a doped polysilicon or a metal layer. Select transistor gate dielectric 322 and bitcell transistor gate dielectric 342 may be a conventionally formed and thermally grown silicon dioxide. In other embodiments, alternative dielectric materials may be used for gate dielectrics 322 and 342. Similarly, although select transistor and bitcell transistor gates 320 and 340 are described as being polysilicon, select transistor and bitcell transistor gates 320 and 340 may employ an additional conductive material for a portion of gates 320 and 340. For example, select transistor gate 320 and bitcell transistor gate 340 may include a polysilicon layer underlying a silicide or another conductive material overlying. In addition, although the embodiment depicted in FIG. 6 employs a single layer of gate dielectric for the select transistor and bitcell transistor gate dielectrics 322 and 342 and a single layer of polysilicon or other material for select transistor and bitcell transistor gates 320 and 340, other implementations may employ different gate dielectrics having different thicknesses and or different dielectric constants for select transistor gate dielectric 322 and bitcell transistor gate dielectric 342. Similarly, two different materials having different thicknesses, different conductivity types, different resistivity, or other different characteristics may be employed for gates 320 and 340.

Although not drawn to scale, FIG. 6 conveys that select transistor gate 320 has different physical dimensions than bitcell transistor gate 340. As shown in FIG. 6, for example, the select transistor 201 appears to have a longer channel length than the bitcell transistor 202.

Turning now to FIG. 7, the depicted cross-section of substrate 301 is taken at a point in the fabrication process in which the lightly-doped source-drain and the extension-halo distributions have been formed in well region 310. In the embodiment depicted in FIG. 7, memory cell 102 includes a bitcell transistor 202 that includes asymmetrically configured source-drain regions. Asymmetrically configured source-drain regions refer to transistors in which the drain region impurity distribution has a depth, doping concentration, or another characteristic that differs from the depth, doping concentration, or other characteristic of the bitcell transistor source region. In some embodiments, the channel region near the transistor source region may have a doping concentration or other characteristic that differs from the doping concentration or other characteristic of the channel region near the transistor drain region. In one embodiment, bitcell transistor 202 includes a more abrupt drain-body junction and a more gradual source-body junction.

Although the order in which the elements depicted in FIG. 7 may be fabricated can vary, some embodiments include forming bitcell transistor proximal drain region 343 in drain zone 567 of bitcell transistor 202. The formation of bitcell transistor proximal drain region 343 in bitcell transistor drain zone 567 may be achieved by a conventional ion implantation of a suitable implant species. For the conductivity types designated in FIG. 7, in which well region 310 is p-type, bitcell transistor proximal drain region 343 is an n-type region which may be formed by implanting arsenic, phosphorus, or another suitable species at a suitable low energy in a range from 1 KeV to 50 KeV using a suitably high dose varying from 5E13 cm⁻² to 5E15 cm⁻². In some embodiments, bitcell transistor proximal drain region 343 has a depth in the range of approximately 0.01-0.2 μm and an impurity concentration in the range of approximately 1E19-1E21 cm⁻³.

Impurities to form bitcell transistor proximal drain region 343 may be selectively introduced into bitcell transistor drain zone 567 by masking portions of well region 310 other than bitcell transistor drain zone 567. In these implementations, the formation of a first portion of a bitcell transistor bitcell transistor proximal drain region 343 does not introduce the impurities into source zone 565 of bitcell transistor 202 or into the source or drain zones 515, 517 of select transistor 201. In other implementations, however, the implantation or other process used to form bitcell transistor proximal drain region 343 may be a nonselective process, in which case, the impurities to form bitcell transistor proximal drain region 343 may be introduced into portions of well region 310 other than the select transistor region. These implementations are represented in FIG. 7 by dotted line 347 within bitcell transistor source zone 565. The shallow distribution represented by reference numeral 347 is shown with a dotted line to convey that, at least in some embodiments, the impurity distribution may be nullified by the subsequent or prior formation of an impurity distribution 346.

Memory cell 102 as depicted in FIG. 7 further includes an impurity distribution, referred to herein as halo distribution 344. As depicted in FIG. 7, halo distribution 344 has a depth that is greater than a depth of bitcell transistor proximal drain region 343. In addition, the conductivity type of halo distribution 344 is opposite the conductivity type of bitcell transistor proximal drain region 343. Halo distribution 344 as shown in FIG. 7 is located within bitcell transistor drain zone 567 underlying bitcell transistor proximal drain region 343 and encroaching laterally into channel zone 561 of bitcell transistor 202. This encroachment may be an intended feature achieved by using a large tilt angle when halo distribution 344 is implanted so that halo distribution 344 encompasses bitcell transistor proximal drain region 343.

FIG. 7 depicts bitcell transistor source region 346 within the same zone 565 of well 310 as the optional impurity distribution represented by reference number 347. In other implementations, during the implant or other process that forms bitcell transistor source region 346, bitcell transistor proximal drain region 343 may be masked so that the impurity distribution is localized to bitcell transistor source zone 565. Thus, by using selective masking, the formation of asymmetrically configured source-drain regions may include forming a relatively more abrupt drain-body junction near drain zone 567 and forming a relatively more gradual source-body junction near source zone 565. Similarly, the halo distribution 344 may be formed within bitcell transistor drain zone 567 and bitcell transistor source zone 565. In this manner, the channel region near the bitcell transistor source region may be counter-doped by the subsequent or prior NLDD implant, giving rise to a relatively less abrupt source-body junction compared with the drain-body junction. In some embodiments, the halo implant is implemented selectively within bitcell transistor drain zone 567 and masked or otherwise excluded from bitcell transistor source zone 565. In these embodiments, bitcell transistor source zone 565 is formed solely with the NLDD implant, which leads to a more gradual source-body junction. In other embodiments, the bitcell transistor source zone 565 may even be counter-doped by a p-type implant, for example, by a PLDD implant, which further lowers the impurity concentration gradient of the source-body junction. As depicted in FIG. 7, halo distribution 344 is p-type distribution that may be formed by implanting boron or another p-type species at a suitably low energy in a range from 1 KeV to 50 KeV using a suitably high dose varying from 5E12 cm⁻² to 5E14 cm⁻². In some embodiments, halo distribution 344 has a depth in the range of approximately 0.02-0.5 microns (μm) and an impurity concentration in the range of approximately 5E17-5E18 cm⁻³.

In some embodiments, bitcell transistor source region 346 may be formed in bitcell transistor source zone 565 by ion implantation of a suitable species, e.g., arsenic or phosphorus and suitable implant energy and implant dose. The implant energy used to form bitcell transistor source region 346 may be in the range of 5 KeV to 100 KeV, and an implant dose may be in the range of 1E13 to 5E14 cm⁻². Again, as described above, the introduction of bitcell transistor source region 346 into bitcell transistor source zone 565 may include introducing an analogous impurity distribution into source zone 515 and drain zone 517 of select transistor 201. Depending upon the implantation recipes, bitcell transistor source region 346 may have a depth in the range of approximately 0.05-0.5 μm, and an impurity concentration of 1E18 to 1E20 cm⁻³.

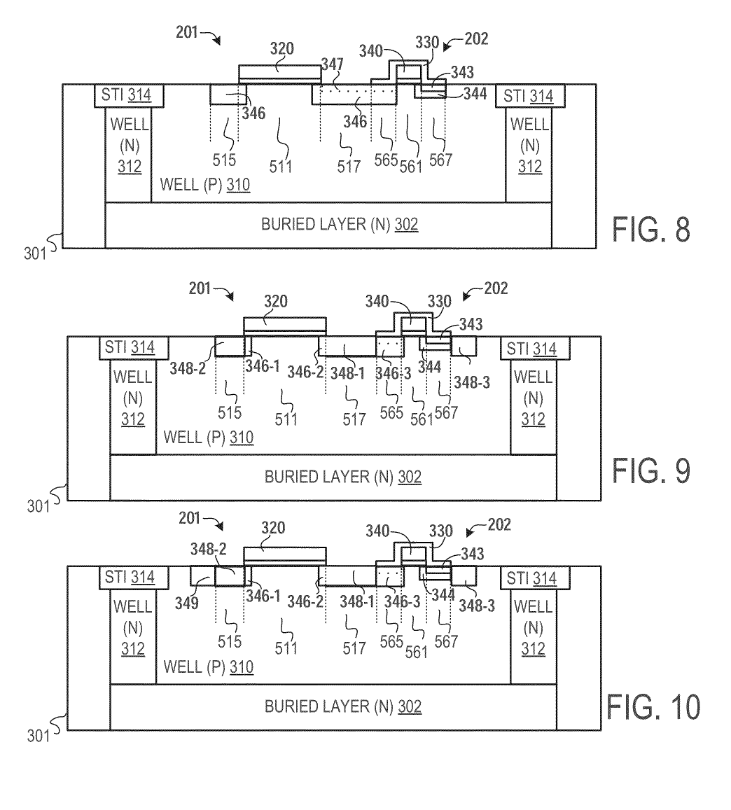

Turning now to FIG. 8, a dielectric layer 330 is depicted formed overlying bitcell transistor source zone 565, bitcell transistor gate 340, and bitcell transistor proximal drain region 343. The dielectric layer 330, which may be formed from silicon dioxide, silicon nitride, another suitable material, or a combination thereof, functions as a silicide prevention layer to prevent silicide from forming on the features of bitcell transistor 202 including bitcell transistor gate 340. The formation of the dielectric layer 330 may be performed prior to or after the formation of heavily-doped source-drain implants described below.

The formation of the dielectric layer 330 may include a masking step to expose selected portions of substrate 301 including the select transistor and the bitcell transistor except the portions of substrate 301 overlying bitcell transistor source, channel, and drain zones 565, 561, and 567. A material such as a metal or a transition metal including, as examples, tantalum, titanium, tungsten, cobalt, nickel or the like, are then deposited. The substrate 301 may then be subjected to a heating step, during which the metal or transition metal reacts with underlying silicon. In these embodiments, the dielectric layer may beneficially improve data retention of bitcell transistor 202.

FIG. 9 depicts a substrate 301 in cross-section after source-drain regions 348 have been formed in first source zone 515, first drain zone 517, and a third drain region adjacent to bitcell transistor drain zone 567 of substrate 301 through ion implantation or other suitable technique. As depicted in FIG. 9, the source-drain implantation introduces three heavily-doped regions 348 into substrate 301. As shown in FIG. 9, heavily-doped region 348 includes a first portion 348-1 located in select transistor drain zone 517, a second portion 348-2 is introduced into a source zone 515 of select transistor 201, and a third region, the bitcell transistor distal drain region 348-3, is introduced into a portion of substrate well 310 adjacent to bitcell transistor drain zone 567. As depicted in FIG. 9, a depth of the heavily-doped regions 348 is shown as approximately equal to a depth of the relatively lightly-doped regions 346 described previously. In these embodiments, it will be appreciated that heavily-doped regions 348 effectively nullify the relatively lightly-doped regions 346. In other embodiments, a depth of the heavily-doped regions 348 may be greater than or less than a depth of the relatively lightly-doped regions 346.

However, FIG. 9 depicts a lateral displacement between heavily-doped regions 348 and select transistor channel zone 511 by a small amount. The displacement of heavily-doped regions 348 leaves small portions of the lightly-doped regions 346 that are in close proximity to the sidewalls of select transistor gate 320. This displacement of heavily-doped regions 348 may be achieved by forming sidewall spacers (not depicted) on sidewalls of select transistor gate 320 as is well known to those of skill in the field of semiconductor fabrication. The small portion of lightly-doped regions 346 that remains uncompensated by heavily-doped regions 348 serves as an LDD element that may beneficially improve the breakdown voltage of select transistor 201 and the transistor hot carrier injection (HCI) performance.

As seen in FIG. 9, the select transistor drain zone 517 and the bitcell transistor source zone 565 are laterally adjacent each other, and form an electrically conductive structure extending between select transistor gate 320 and bitcell transistor gate 340. Thus, as depicted in FIG. 9, drain zone 517 of select transistor 201 and source zone 565 of bitcell transistor 202 overlap to form a shared terminal. In other embodiments, drain zone 517 of select transistor 201 and source zone 565 of bitcell transistor 202 may be laterally separated regions connected with each other via interconnect or metal layers.

Turning now to FIG. 10, a heavily-doped region 349 is depicted as being formed adjacent to heavily-doped region 348-2 in select transistor source zone 515. The heavily-doped region 349 is of a conductivity type that is opposite the conductivity type of heavily-doped region 348-2. In the implementation depicted in FIG. 10 in which well 310 is of a p-type conductivity, heavily-doped region 349 is also a p-type region. Heavily-doped region 349 provides an ohmic contact through well region 310. As depicted in FIG. 10, region 349 has an approximately equal depth as region 348-2. Region 349 and region 348-2 are connected by the silicide overlying, and are biased with the same potential during the operation of the memory cell.

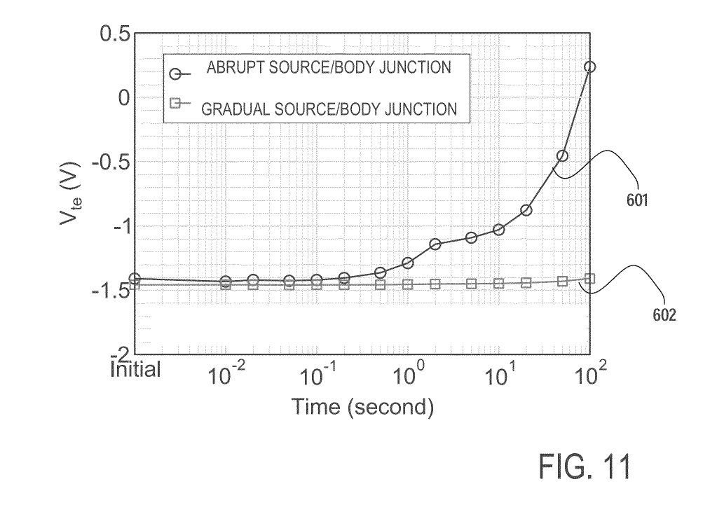

Turning now to FIG. 11, program disturb immunity improvement that may be achieved using an embodiment is represented by two curves of the threshold voltage of unselected cells as a function of disturb time. The ratio of the disturb time and the programming time for each bitcell represents the number of disturbs experienced during programming of single polysilicon NVM array, which is determined by the array size. The plot 601 depicts the erase threshold voltage as a function of disturb time for an unselected cell in a memory cell having symmetrical source and drain regions. This cell is on an unselected word-line and on the selected bit-line. For this type of bit cell, plot 601 reveals program disturb begins to occur around 0.5 seconds and increases exponentially thereafter. In contrast, the curve 602 depicts the program disturb characteristics of an embodiment of a bit cell that incorporates the elements depicted and described with respect to FIG. 5 through FIG. 10 including asymmetrically configured source-body and drain-body junctions. As curve 602 indicates, there is no appreciable increase in threshold voltage of unselected bitcells during programming of a selected bitcell up to 100 seconds of disturb time.

Although disclosed subject matter is described herein with reference to specific embodiments, various modifications and changes can be made without departing from the scope of the subject matter as set forth in the claims below. Accordingly, the specification and figures are to be regarded as illustrative rather than restrictive and the modifications and changes referred to are intended to be included within the scope of the present invention. Unless expressly stated otherwise, any benefits, advantages, or solutions to problems that are described herein with regard to specific embodiments are not intended to be construed as critical, required, or essential features or elements of any or all the claims.

Similarly, unless expressly stated otherwise, terms such as “first” and “second” may be used solely to distinguish between different elements such terms describe. Thus, these terms are not necessarily intended to indicate temporal or other prioritization of such elements.

What is claimed is:

1. A method, comprising:
forming a select transistor gate overlying a select transistor channel region of a substrate, the select transistor channel region laterally positioned between a select transistor source region and a select transistor drain region;
forming a bitcell transistor gate overlying a bitcell transistor channel region of the substrate;
forming a proximal drain region of the bitcell transistor adjacent to the bitcell transistor channel region, wherein the proximal drain region forms a drain-body junction with a transistor body of the bitcell transistor; and
forming a bitcell transistor source region adjacent to the bitcell transistor channel region, wherein the bitcell transistor source region forms a source-body junction with the transistor body;
wherein an impurity concentration gradient of the drain-body junction is greater than an impurity concentration gradient of the source-body junction.

2. The method of claim 1, wherein the bitcell transistor gate comprises an electrically isolated transistor gate.

3. The method of claim 1, wherein the substrate includes a well region, the proximal drain region and the bitcell transistor source region have a first conductivity type, and the well region has a second conductivity type that is different than the first conductivity type.

4. The method of claim 3, wherein a depth of the proximal drain region is less than a depth of the bitcell transistor source region.

5. The method of claim 4, further comprising forming a halo distribution of the second conductivity type encompassing the proximal drain region, wherein the halo distribution is deeper and less heavily-doped than the proximal drain region.

6. The method of claim 5, wherein the halo distribution is less heavily-doped than the bitcell transistor source region.

7. The method of claim 1, further comprising forming a heavily-doped source in the select transistor source region and a heavily-doped drain in the select transistor drain region.

8. The method of claim 7, further comprising forming a silicide prevention layer overlying the bitcell transistor gate, the bitcell transistor source region, and the proximal drain region.

9. The method of claim 8, wherein forming the silicide prevention layer includes forming a dielectric layer overlying the bitcell transistor gate, the bitcell transistor source region, and the proximal drain region.

10. The method of claim 7, further comprising, prior to forming the heavily-doped source and heavily-doped drain, forming spacers on sidewalls of the select transistor gate, wherein the heavily-doped source and heavily-doped drains are laterally aligned to the spacers.

11. The method of claim 1, further comprising forming a coupling capacitor including a first plate, a capacitor dielectric underlying the first plate, and a substrate plate.

12. The method of claim 11, wherein the first plate is a polycrystalline plate connected to the bitcell transistor gate and wherein the substrate plate comprises:
a central portion underlying the first capacitor plate; and
a substrate tie surrounding the central portion, wherein the substrate tie includes a portion having the second conductivity type.

13. A nonvolatile memory device comprising an array of memory cells, wherein each of the memory cells includes:
a select transistor comprising:
a select transistor gate overlying a select transistor channel region;
a select transistor source region adjacent to the select transistor channel region; and
a select transistor drain region adjacent to the select transistor channel region, wherein the select transistor channel region is positioned between the select transistor source region and the select transistor channel region; and
a bitcell transistor, comprising:
a bitcell transistor gate overlying a bitcell transistor channel region of a bitcell transistor body;
a bitcell transistor source region adjacent to the bitcell transistor channel region; and
a bitcell transistor proximal drain region adjacent to the bitcell transistor channel region, wherein the bitcell transistor channel region is positioned between the bitcell transistor source region and the bitcell transistor proximal drain region;
wherein an impurity concentration gradient of a junction between the bitcell source region and the bitcell transistor body is less than an impurity concentration gradient of a junction between the bitcell drain region and the bitcell transistor body.

14. The nonvolatile memory of claim 13, wherein the bitcell transistor gate comprises an Ohmically isolated transistor gate.

15. The nonvolatile memory of claim 13, wherein the bitcell transistor gate is connected to a first electrode of a coupling capacitor.

16. The nonvolatile memory of claim 15, wherein the coupling capacitor includes a first plate, a capacitor dielectric underlying the first plate, and a substrate plate, wherein the first plate is a polycrystalline plate and the substrate plate includes:
a central portion underlying the first capacitor plate; and
a substrate tie including a portion having the second conductivity type.

17. A method of fabricating a nonvolatile memory, the method comprising:
forming a memory cell, the memory cell comprising:
a select transistor comprising symmetrically configured source-drain regions; and
a bitcell transistor comprising asymmetrically configured source-drain regions and an Ohmically isolated transistor gate;
wherein an impurity concentration gradient of a source-body junction of the bitcell transistor is less than an impurity concentration gradient of a drain-body junction of the bitcell transistor.

18. The method of claim 17, wherein a gate of the select transistor and a gate of the bitcell transistor are both formed during a single gate formation fabrication sequence.

19. The method of claim 17, wherein the drain-body junction includes a heavily-doped drain impurity distribution adjacent an oppositely-doped halo impurity distribution and wherein the source-body junction includes an extension implant region adjacent an oppositely-doped well region.

20. The method of claim 19, further comprising a coupling capacitor, the coupling capacitor including a first plate, a capacitor dielectric underlying the first plate, and a substrate plate, wherein the first plate is a polycrystalline plate and the substrate plate includes:
a central portion underlying the first capacitor plate; and
a substrate tie surrounding the central portion, wherein the substrate tie includes a first portion having the first conductivity type and a second portion having the second conductivity type.
